(19) United States
(12) Patent Application Publication
(10) Pub. No.: US 2013/0285066 A1
(43) Pub. Date: Oct. 31, 2013

(54) METHOD OF FABRICATING GALLIUM NITRIDE SEMICONDUCTOR, METHOD OF FABRICATING GROUP III NITRIDE SEMICONDUCTOR DEVICE, AND GROUP III NITRIDE SEMICONDUCTOR DEVICE

(71) Applicant: SUMITOMO ELECTRIC INDUSTRIES, LTD., Osaka-shi (JP)

(72) Inventors: Takamichi SUMITOMO, Itami-shi (JP); Masaki UENO, Itami-shi (JP); Yusuke YOSHIZUMI, Itami-shi (JP); Yohei ENYA, Itami-shi (JP)

(73) Assignee: Sumitomo Electric Industries, Ltd., Osaka-shi (JP)

(21) Appl. No.: 13/871,760

(22) Filed: Apr. 26, 2013

(30) Foreign Application Priority Data
Apr. 27, 2012 (JP) 2012-103685

(51) Int. Cl. H01L 33/00; H01L 33/30

(52) U.S. Cl. CPC H01L 33/0062; H01L 33/305
USPC 257/76; 438/542; 438/45

(57) ABSTRACT

Provided is a method of fabricating a gallium nitride semiconductor which enables activation of a p-type dopant with a heat treatment performed for a relatively short period of time. The fabricating method comprises the step of performing, in a vacuum, a heat treatment of a group III nitride semiconductor region, the group III nitride semiconductor region comprising a gallium nitride semiconductor, the gallium nitride semiconductor including a p-type dopant, the a group III nitride semiconductor region having a group III nitride semiconductor surface inclined with respect to a reference plane perpendicular to a reference axis, and the reference axis extending in a direction of a c-axis of the gallium nitride semiconductor.

### BACKGROUND OF THE INVENTION

1. Field of the Invention

The present invention relates to a method of fabricating a gallium nitride semiconductor, a method of fabricating a group III nitride semiconductor device, and a group III nitride semiconductor device.

2. Related Background Art

Patent Literature 1 discloses fabricating a p-type GaN layer on a c-plane sapphire substrate in a reactor of a MOCVD apparatus. Patent Literature 2 discloses applying ambient atmosphere conditions (average temperature 28 degrees Celsius, average relative humidity 68%) to a heating atmosphere of a heating treatment. Patent Literature 3 discloses annealing a gallium nitride compound semiconductor layer doped with p-type impurity.

Patent Literature 1: Japanese Patent Application Laid-open No. H10-12624

Patent Literature 2: Japanese Patent Application Laid-open No. 2007-180564

Patent Literature 3: Japanese Patent Application Laid-open No. H5-183189

### SUMMARY OF THE INVENTION

Patent Literature 1 discloses variations in resistivity and hole concentration of a p-type GaN layer when a heat treatment time is varied from 1 minute to 100 minutes at a heat treatment temperature set to 1000 degrees Celsius. Under the heat treatment temperature according to Patent Literature 1, both resistivity and hole concentration improve as the heat treatment time increases.

The c-plane sapphire substrate on which the p-type GaN layer is grown is placed on a carbon susceptor, and the carbon susceptor is inserted into a silica tube. Subsequently, while supplying nitrogen gas and trimethylamine (N(CH₃)₃) into the silica tube, infrared irradiation with an infrared lamp is performed in a heating furnace to rapidly heat the c-plane sapphire substrate.

In Patent Literature 2, a p-type guide layer made of p-type GaN to which magnesium (Mg) has been added as p-type impurity, a p-type cladding layer constituted by a p-type AlGaN mixed crystal layer to which magnesium (Mg) has been added as p-type impurity, and a p-side contact layer constituted by a p-type GaN layer to which magnesium (Mg) has been added as p-type impurity are sequentially grown on an active layer on a sapphire substrate. Cyclopentadienyl magnesium gas is used as a Mg source. In an experiment, a sapphire substrates mounted with the semiconductor layer described above is placed on a stainless-steel heating plate respectively heated to 385 degrees Celsius, 415 degrees Celsius, and 485 degrees Celsius, and a stainless-steel weight was placed on the sapphire substrate to increase adhesion between the heat treatment evaluation sample and the heating plate. Ambient atmosphere conditions (average temperature 28 degrees Celsius, average relative humidity 68%) were used as a heating atmosphere. Heat treatment at heat treatment temperatures of 400 degrees Celsius and 385 degrees Celsius yielded a carrier concentration of 1×10¹⁸ cm⁻³ when performed for heat treatment times of, respectively, 41 hours and 82 hours.

Patent Literature 3 discloses annealing a gallium nitride compound semiconductor layer doped with p-type impurity. Annealing was performed in a nitrogen atmosphere subject to pressure that is equal to or greater than a decomposition pressure of a gallium nitride compound semiconductor at an annealing temperature. The application of pressure to a nitrogen atmosphere can prevent nitrogen (N) included in the gallium nitride compound semiconductor from decomposing during annealing to be released. In the case of GaN, the decomposition pressure of GaN is approximately 0.01 atmospheres at 800 degrees Celsius, approximately 1 atmosphere at 1000 degrees Celsius, and approximately 10 atmospheres at 1100 degrees Celsius. This pressurization can prevent decomposition of a gallium nitride compound semiconductor which occurs when the gallium nitride compound semiconductor is annealed at 400 degrees Celsius or higher, so that deterioration of crystallinity can be avoided. In addition, the heat treatment time in the individual examples is 20 minutes.

As shown in the documents listed above, heat treatment in a nitrogen atmosphere reduces specific resistance of a semiconductor due to facilitation of activation of a p-type dopant. Obtaining further hydrogen desorption using heat treatment in a nitrogen atmosphere requires extending heat treatment time. Accordingly, what is needed is to enable greater hydrogen desorption with a heat treatment over a shorter period of time as compared to heat treatment in a nitrogen atmosphere. According to findings compiled by the present inventors, with a semipolar surface that differs from a c-plane, treatment in a nitrogen atmosphere designed to achieve desired activation reduces the quality of the semipolar surface that is to be exposed to the nitrogen atmosphere.

One aspect of the present invention has been made in consideration of such circumstances, and it is an object of the present invention to provide a method of fabricating a gallium nitride semiconductor which enables activation of a p-type dopant with a heat treatment performed over a relatively short period of time. It is an object of another aspect of the present invention to provide a method of fabricating a group III nitride semiconductor device which enables activation of a p-type dopant with a heat treatment performed over a relatively short period of time. It is an object of yet another aspect of the present invention is to provide a group III nitride semiconductor device which has a layer with low resistance due to activation of a p-type dopant.

A method of fabricating a gallium nitride semiconductor exhibiting p-type conductivity according to one aspect of the present invention comprises the step of (a) performing, in a vacuum, a heat treatment of a group III nitride semiconductor region which comprises a gallium nitride semiconductor including a p-type dopant and which has a group III nitride semiconductor surface that is inclined relative to a reference plane perpendicular to a reference axis extending in a direction of a c-axis of the gallium nitride semiconductor.

According to this method of fabricating a gallium nitride semiconductor (hereinafter, referred to as a “fabrication method”), the gallium nitride semiconductor includes a p-type dopant, and this gallium nitride semiconductor is included in a group III nitride semiconductor region. A heat treatment of the group III nitride semiconductor region and the group III nitride semiconductor surface is performed in a vacuum enables activation of the gallium nitride semiconductor in the semiconductors to occur. In addition, a heat treatment using a vacuum enables greater hydrogen desorption due to the relevant heat treatment as compared to a heat treatment in a nitrogen atmosphere. Furthermore, a heat treatment in a vacuum reduces the decline in quality of the group III nitride semiconductor surface in terms of achieving a desired specific resistance.

The method of fabricating a gallium nitride semiconductor exhibiting p-type conductivity according to the aspect of the present invention can further comprise the step of preparing a substrate having a semipolar surface made of a hexagonal group III nitride. The group III nitride based semiconductor region is favorably provided on the semipolar surface of the substrate.

According to this fabrication method, when the group III nitride semiconductor region is provided on the semipolar surface of the substrate, a surface of the group III nitride semiconductor region that is grown on the semipolar surface inherits a plane orientation of the substrate, and becomes a semipolar surface. In the heat treatment, the semipolar surface exhibits characteristics that differ from those of a c-plane.

In the method of fabricating a gallium nitride semiconductor exhibiting p-type conductivity according to the aspect of the present invention, a degree of vacuum for the heat treatment is favorably equal to or lower than 1×10⁻⁵ Torr.

According to this fabrication method, a degree of vacuum equal to or lower than 1×10⁻⁵ Torr (1.33322×10⁻³ Pascal) is favorably used.

In the method of fabricating a gallium nitride semiconductor exhibiting p-type conductivity according to the aspect of the present invention, a degree of vacuum for the heat treatment is more favorably equal to or lower than 7.5×10⁻⁸ Torr.

According to this fabrication method, the degree of vacuum that is equal to or lower than 7.5×10⁻⁸ Torr (1×10⁻⁵ pascal) or, in other words, under an ultrahigh vacuum can promote activation of the gallium nitride semiconductor.

In the method of fabricating a gallium nitride semiconductor exhibiting p-type conductivity according to the aspect of the present invention, the heat treatment is favorably performed at a temperature equal to or higher than 650 degrees Celsius.

According to this fabrication method, a heat treatment performed at a temperature equal to or higher than 650 degrees Celsius is capable of achieving relatively significant hydrogen desorption.

In the method of fabricating a gallium nitride semiconductor exhibiting p-type conductivity according to the aspect of the present invention, the heat treatment is favorably performed at a temperature equal to or lower than 700 degrees Celsius.

According to this fabrication method, a heat treatment performed at a temperature equal to or lower than 700 degrees Celsius is capable of reducing significant nitrogen desorption from the group III nitride semiconductor surface.

In the method of fabricating a gallium nitride semiconductor exhibiting p-type conductivity according to the aspect of the present invention, the semipolar surface can be inclined in a direction from a c-axis of the group III nitride to an m-axis of the group III nitride, and an angle of the inclination can be 63 degrees or more and less than 80 degrees.

According to this fabrication method, unlike a c-plane constituted by an array of gallium atoms or an array of nitrogen atoms, both of gallium atoms and nitrogen atoms are arranged to appear on the semipolar surface. Both gallium atoms and nitrogen atoms appear on a surface within an angle range of 63 degrees or more and less than 80 degrees.

The method of fabricating a gallium nitride semiconductor exhibiting p-type conductivity according to the aspect of the present invention can further comprise the step of supplying a dopant material for a p-type dopant, a metalorganic group III material, and a nitrogen material to a growth reactor to grow the gallium nitride semiconductor.

According to this fabrication method, during growth using the metalorganic group III material, hydrogen included in the metalorganic group III material remains in the gallium nitride semiconductor.

In the method of fabricating a gallium nitride semiconductor exhibiting p-type conductivity according to the aspect of the present invention, the p-type dopant can include magnesium.

According to this fabrication method, for example, magnesium can be used as the p-type dopant. In a gallium nitride semiconductor grown by use of a material including hydrogen, the hydrogen bonds to the magnesium in the gallium nitride semiconductor.

In the method of fabricating a gallium nitride semiconductor exhibiting p-type conductivity according to the aspect of the present invention, the gallium nitride semiconductor can comprise GaN, InGaN, AlGaN, or InAlGaN.

According to this fabrication method, the gallium nitride semiconductor can be at least any of GaN, InGaN, AlGaN, and InAlGaN, and can further be In_{T}Al_{S}Ga_{1-S-T}N (0≦S≦1, 0≦T≦1).

A method of fabricating a group III nitride semiconductor device including a gallium nitride semiconductor exhibiting p-type conductivity according to another aspect of the present invention comprises the steps of: (a) performing, in a vacuum, a heat treatment of a group III nitride semiconductor region which comprises a gallium nitride semiconductor including a p-type dopant and which has a group III nitride semiconductor surface that is inclined relative to a reference plane perpendicular to a reference axis extending in a direction of a c-axis of the gallium nitride semiconductor; and (b) forming an electrode on the group III nitride semiconductor surface.

According to this method of fabricating a group III nitride semiconductor device (hereinafter, referred to as a “fabrication method”), the gallium nitride semiconductor includes a p-type dopant and the gallium nitride semiconductor is included in a group III nitride semiconductor region. When a heat treatment of the group III nitride semiconductor region and the group III nitride semiconductor surface is performed in a vacuum, activation of the gallium nitride semiconductor occurs in the semiconductors. In addition, a heat treatment in a vacuum enables greater hydrogen desorption in a shorter period of time required for the heat treatment as compared to a heat treatment in a nitrogen atmosphere. Furthermore, a decline in quality of the group III nitride semiconductor surface when achieving a desired specific resistance is reduced.

The method of fabricating a group III nitride semiconductor device according to the other aspect of the present invention can further comprise the step of preparing a substrate having a semipolar surface made of a hexagonal group III nitride. The group III nitride semiconductor region is favorably provided on the semipolar surface of the substrate.

According to this fabrication method, when the group III nitride based semiconductor region is provided on the semipolar surface of the substrate, a surface of the group III nitride semiconductor region that is grown on the semipolar surface inherits a plane orientation of the substrate and also becomes a semipolar surface. In the heat treatment, the semipolar surface exhibits characteristics that differ from those of a c-plane.

In the method of fabricating a group III nitride semiconductor device according to the other aspect of the present invention, the formation of the electrode can be performed after the heat treatment.

According to this fabrication method, when the electrode is formed on the group III nitride semiconductor surface after the heat treatment in a vacuum, a deterioration of contact resistance of the electrode can be avoided.

In the method of fabricating a group III nitride semiconductor device according to the other aspect of the present invention, a degree of vacuum during the heat treatment is favorably equal to or lower than 1×10⁻⁵ Torr.

According to this fabrication method, a degree of vacuum equal to or lower than 1×10⁻⁵ Torr (1.33322×10⁻³ Pascal) is favorably used in the heat treatment.

In the method of fabricating a group III nitride semiconductor device according to the other aspect of the present invention, a degree of vacuum during the heat treatment is favorably equal to or lower than 7.5×10⁻⁸ Torr.

According to this fabrication method, the degree of vacuum that is equal to or lower than 7.5×10⁻⁸ Torr (1×10⁻⁵ Pascal) or, in other words, under an ultrahigh vacuum, can promote the activation in the gallium nitride semiconductor.

In the method of fabricating a group III nitride semiconductor device according to the other aspect of the present invention, the heat treatment is favorably performed in a temperature range of 650 degrees Celsius or higher and 700 degrees Celsius or lower.

According to this fabrication method, a heat treatment performed at a temperature equal to or higher than 650 degrees Celsius is capable of achieving relatively significant hydrogen desorption. In addition, a heat treatment performed at a temperature equal to or lower than 700 degrees Celsius is capable of reducing nitrogen desorption from the group III nitride semiconductor surface.

In the method of fabricating a group III nitride semiconductor device according to the other aspect of the present invention, favorably, the semipolar plane is inclined in a direction from a c-axis of the group III nitride to an m-axis of the group III nitride, and an angle range of the inclination is 63 degrees or more and less than 80 degrees.

According to this fabrication method, unlike a c-plane that an array of gallium atoms or an array of nitrogen atoms constitutes, the array of both gallium atoms and nitrogen atoms appear on the semipolar plane. Both gallium atoms and nitrogen atoms appear on the same surface that tilts within an angle range of 63 degrees or more and less than 80 degrees.

The method of fabricating a group III nitride semiconductor device according to the other aspect of the present invention can further comprise the step of supplying a dopant material for a p-type dopant, a metalorganic group III material, and a nitrogen material to a growth reactor to grow the gallium nitride semiconductor. The heat treatment can be performed by an apparatus that differs from the growth reactor, and this apparatus can include a chamber capable of achieving pressure that is lower than pressure used for film formation.

According to this fabrication method, during growth using the metalorganic group III material, hydrogen of the metal-organic group III material is left in the gallium nitride semiconductor.

The method of fabricating a group III nitride semiconductor device according to the other aspect of the present invention can further comprise the step of supplying a metalorganic group III material and a nitrogen material to a growth reactor to grow an active layer composed of a gallium nitride semiconductor.

According to this fabrication method, a light-emitting device is provided with low contact resistance in addition to a p-type gallium nitride semiconductor with low layer resistance.

In the method of fabricating a group III nitride semiconductor device according to the other aspect of the present invention, the active layer can be provided so as to emit light of a wavelength in a range of 480 nm or more and 540 nm or less.

According to this fabrication method, emission of light with a green wavelength and nearby wavelengths can be provided.

In the method of fabricating a group III nitride semiconductor device according to an aspect of the present invention, the active layer can be provided so as to generate light having a wavelength in a range of 510 nm or more and 540 nm or less.

According to this fabrication method, emission of light in a green wavelength region can be provided.

In a method of fabricating a group III nitride semiconductor device according to the other aspect of the present invention, favorably, the group III nitride semiconductor surface is constituted by a p-type gallium nitride semiconductor, the p-type gallium nitride semiconductor includes a p-type dopant and hydrogen, and a hydrogen concentration of the p-type gallium nitride semiconductor is equal to or lower than 10 percent of a p-type dopant concentration of the p-type gallium nitride semiconductor.

According to this fabrication method, the heat treatment in a vacuum is capable of promoting hydrogen desorption from the p-type gallium nitride semiconductor and, as a result, the hydrogen concentration of the p-type gallium nitride semiconductor can be reduced so as to equal or fall below 10 percent of the p-type dopant concentration of the p-type gallium nitride semiconductor.

In the method of fabricating a group III nitride semiconductor device according to the other aspect of the present invention, the gallium nitride semiconductor can comprise GaN, InGaN, AlGaN, or InAlGaN. The p-type dopant favorably includes magnesium.

According to this fabrication method, for example, magnesium can be used as the p-type dopant. In a gallium nitride semiconductor grown by use of a material including hydrogen, the hydrogen bonds to magnesium. In addition, the gallium nitride semiconductor can be at least any of GaN, InGaN, AlGaN, and InAlGaN, and can further be In_{T}Al_{S}Ga_{1-S-T}N (0≦S≦1, 0≦T≦1).

A group III nitride semiconductor device according to yet another aspect of the present invention comprises: (a) a substrate; (b) an active layer which is provided on a primary surface of the substrate and which is composed of gallium nitride semiconductor; and (c) a p-type gallium nitride semiconductor region which is provided on the primary surface of the substrate and which has a gallium nitride semiconductor surface. The gallium nitride semiconductor surface is inclined relative to a reference plane perpendicular to the reference axis that extends in a direction of a c-axis of the p-type gallium nitride semiconductor region, the p-type gallium nitride semiconductor region includes a p-type dopant and hydrogen, and a hydrogen concentration of the p-type gallium nitride semiconductor region is equal to or lower than 10 percent of a p-type dopant concentration of the p-type gallium nitride semiconductor region.

According to this group III nitride semiconductor device, since the hydrogen concentration of the p-type gallium nitride semiconductor is reduced so as to equal or fall below 10 percent of the p-type dopant concentration of the p-type gallium nitride semiconductor, a specific resistance of the p-type gallium nitride semiconductor can be reduced. Therefore, a decrease in quality during operation which is attributable to the incorporated hydrogen can be reduced.

The group III nitride semiconductor device according to the other aspect of the present invention can further comprise an electrode that is joined to the gallium nitride semiconductor surface of the p-type gallium nitride semiconductor region. A junction interface between the electrode and the gallium nitride semiconductor surface of the p-type gallium nitride semiconductor region is favorably inclined relative to a reference plane perpendicular to an axis extending in a direction of a c-axis of the p-type gallium nitride semiconductor region.

According to this group III nitride semiconductor device, when the hydrogen concentration of the p-type gallium nitride semiconductor providing the gallium nitride semiconductor surface is reduced so as to equal or fall below 10 percent of the p-type dopant concentration of the p-type gallium nitride semiconductor, a contact resistance of the p-type gallium nitride semiconductor can be reduced.

A group III nitride semiconductor device according to yet another aspect of the present invention can further comprise an n-type gallium nitride semiconductor region provided on the substrate. Favorably, the substrate includes a primary surface constituted by a group III nitride, the primary surface of the substrate exhibits a semipolar nature, the n-type gallium nitride semiconductor region, the active layer, and the p-type gallium nitride semiconductor region are arranged in a direction of an axis normal to the primary surface of the substrate, the normal axis is inclined relative to the reference axis, and the active layer is provided between the n-type gallium nitride semiconductor region and the p-type gallium nitride semiconductor region.

According to the group III nitride semiconductor device, the use of the substrate exhibiting semipolar characteristics allows providing a high-quality semiconductor due to the contribution by the primary surface constituted by a group III nitride. Accordingly, the gallium nitride semiconductor surface also has preferable crystalline quality.

In the group III nitride semiconductor device according to the other aspect of the present invention, the inclination can be formed in a direction from a c-axis to an m-axis of the p-type gallium nitride semiconductor region and an angle of the inclination can be in a range of 63 degree or more and less than 80 degrees.

According to this group III nitride semiconductor device, unlike a c-plane constituted by any of an array of gallium atoms and an array of nitrogen atoms, the semipolar surface has an arrangement of an array of both gallium atoms and nitrogen atoms. Both gallium atoms and nitrogen atoms appear on a surface within an angle range of 63 degrees or more and less than 80 degrees.

In the group III nitride semiconductor device according to the other aspect of the present invention, the active layer is favorably provided so as to emit light of a wavelength in a range of 480 nm or more and 540 nm or less. This group III nitride semiconductor device can emit light with a green wavelength and nearby wavelengths.

In the group III nitride semiconductor device according to the other aspect of the present invention, the active layer is favorably provided so as to emit light having a wavelength in a range of 510 nm or more and 540 nm or less. This group III nitride semiconductor device can provide emission of light in a green wavelength region.

In the group III nitride semiconductor device according to the other aspect of the present invention, the p-type dopant favorably includes magnesium. According to this group III nitride semiconductor device, for example, magnesium can be used as the p-type dopant. In a gallium nitride semiconductor grown by supplying a material including hydrogen, the hydrogen bonds to magnesium.

### BRIEF DESCRIPTION OF THE DRAWINGS

The above and other objects, features, and advantages of the present invention will be more readily understood by reference to the following detailed description of preferred embodiments of the present invention when taken in connection with the accompanying drawings.

FIG. 1 is a diagram schematically showing structures of a group III nitride semiconductor device and an epitaxial substrate according to a present embodiment;

FIG. 2 is a diagram showing major steps in a method of fabricating a nitride semiconductor laser according to the present embodiment;

FIG. 3 is a diagram showing major steps in the method of fabricating a nitride semiconductor laser according to the present embodiment;

FIG. 4 is a diagram schematically showing steps in the method of fabricating a nitride semiconductor laser according to the present embodiment;

FIG. 5 is a diagram schematically showing a structure of a group III nitride semiconductor laser fabricated in a first example;

FIG. 6 is a diagram showing an example of a temperature profile of a heat treatment according to an embodiment;

FIG. 7 is a diagram showing a relationship between heat treatment time and contact resistance under atmospheric pressure;

FIG. 8 is a diagram showing a relationship between heat treatment time and specific resistance of a p-type semiconductor layer according to an example;

FIG. 9 is a diagram showing a relationship between degree of vacuum and a p-type GaN layer in a heat treatment according to an example; and

FIG. 10 is a diagram showing a relationship between heat treatment temperature and specific resistance.

### DESCRIPTION OF THE PREFERRED EMBODIMENTS

The teachings of the present invention will be readily understood upon consideration of the following detailed description with reference to the accompanying drawings. Embodiments of a method of fabricating a gallium nitride semiconductor having p-type conductivity, a method of fabricating a group III nitride semiconductor device, and a group III nitride semiconductor device according to the present invention will now be described with reference to the accompanying drawings. Whenever appropriate, like portions will be denoted by like reference characters.

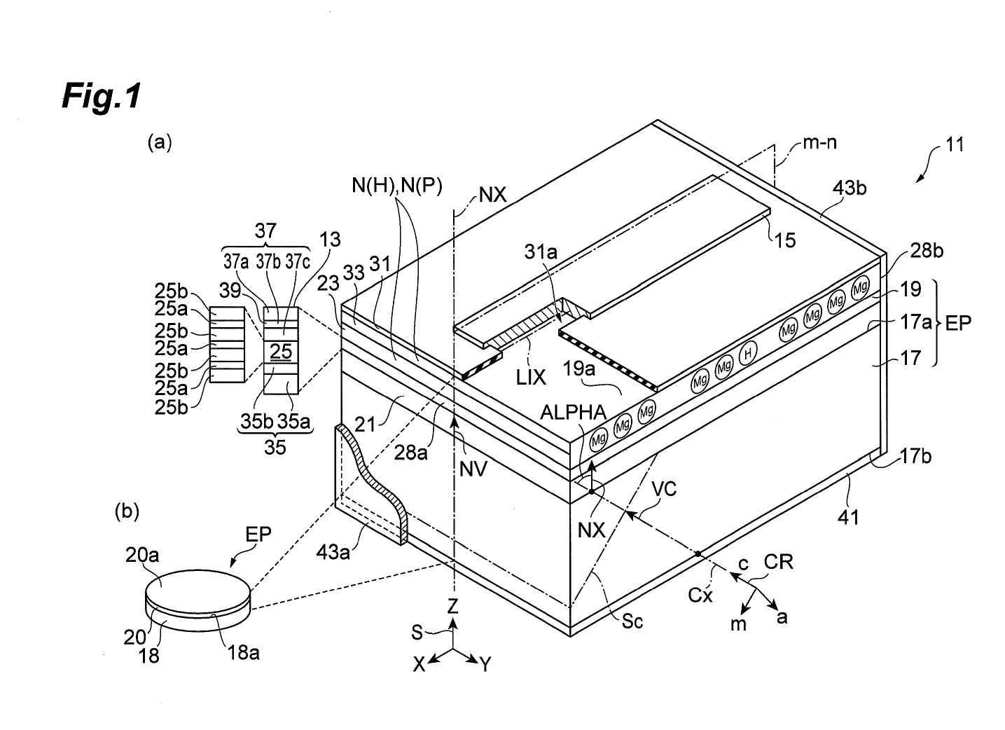

FIG. 1 is a schematic view showing structures of a group III nitride semiconductor device and an epitaxial substrate according to the present embodiment. While a group III nitride semiconductor laser 11 will be described below as a group III nitride semiconductor device, activation of a semiconductor including a p-type dopant is not limited to any particular device structure but is applicable to group III nitride semiconductor devices with various structures. In addition, as shown in Part (a) of FIG. 1, while the group III nitride semiconductor laser 11 has a gain guiding structure, embodiments of the present invention are not limited to a gain guiding structure and may alternatively have, for example, a ridge structure. The group III nitride semiconductor laser 11 includes a supporting base 17 and a semiconductor region 19. As shown in Part (b) of FIG. 1, an epitaxial substrate EP for the group III nitride semiconductor laser 11 includes a substrate 18 in place of the supporting base 17 and, at the same time, includes a semiconductor laminate 20 in place of the semiconductor region 19. A layer structure of the semiconductor laminate 20 is the same as that of the semiconductor region 19. The semiconductor laminate 20 is provided on a semipolar surface 18a of the substrate 18. The epitaxial substrate EP does not include an electrode.

While the group III nitride semiconductor laser 11 will now be described, the description also applies to the epitaxial substrate EP for the nitride semiconductor laser 11. As shown in Part (a) of FIG. 1, the nitride semiconductor laser 11 comprises an n-type cladding layer 21, a p-type cladding layer 23, and an active layer 25. Meanwhile, the epitaxial substrate EP comprises a first semiconductor layer for the n-type cladding layer 21, a second semiconductor layer for the p-type cladding layer 23, and a third semiconductor layer for the active layer. In the group III nitride semiconductor laser 11, the active layer 25 is included in an emission layer 13, and the emission layer 13 is provided between the n-type cladding layer 21 and the p-type cladding layer 23. The emission layer 13 acts as a core semiconductor region that is provided between the n-type cladding layer 21 and the p-type cladding layer 23. The semiconductor region 19 includes the emission layer 13, the n-type cladding layer 21, and the p-type cladding layer 23. The n-type cladding layer 21 is composed of a first nitride semiconductor including indium and aluminum as group III constituent elements. The p-type cladding layer 23 is composed of a second nitride semiconductor including indium and aluminum as group III constituent elements. The active layer 25 includes an epitaxial layer composed of a nitride semiconductor including indium as a constituent element. The active layer 25 is provided so as to generate light of a peak wavelength within a wavelength range of 480 nm or more and 540 nm or less. Refractive indices of the n-type cladding layer 21 and the p-type cladding layer 23 are smaller than a refractive index of GaN. In addition, an electrode 15 is provided on the semiconductor region 19 and an electrode 41 is provided on a back plane 17b of the supporting base 17.

As is apparent from FIG. 1, the group III nitride semiconductor laser 11 (the epitaxial substrate EP) comprises a p-type gallium nitride semiconductor region (for example, composed of the p-type cladding layer 23, furthermore by a p-type contact layer 33, and still furthermore by an electron blocking layer 39) provided on the supporting base 17 (the substrate 18). The p-type gallium nitride semiconductor region includes a gallium nitride semiconductor surface (the surface 19), and the gallium nitride semiconductor surface (the surface 19) is inclined relative to a reference place that is perpendicular to a reference axis extending in a direction of a c-axis of the p-type gallium nitride semiconductor region. The p-type gallium nitride semiconductor region includes a p-type dopant and hydrogen. A hydrogen concentration of the p-type gallium nitride semiconductor region, for example, a hydrogen concentration N(H) of the p-type cladding layer 23, furthermore a hydrogen concentration N(H) of the p-type contact layer 33, and still furthermore a hydrogen concentration N(H) of the electron blocking layer 39, is equal to or lower than 10 percent of a p-type dopant concentration N(p) of the p-type gallium nitride semiconductor region. In addition, the group III nitride semiconductor laser 11 (the epitaxial substrate EP) comprises an n-type gallium nitride semiconductor region (for example, composed of an n-type cladding layer 21, and furthermore by a n-type buffer layer) provided on the supporting base 17 (the substrate 18).

According to this nitride semiconductor laser 11, when the hydrogen concentration N(H) of the p-type gallium nitride semiconductor is reduced so as to equal or fall below 10 percent of the p-type dopant concentration N(p) of the p-type gallium nitride semiconductor, a specific resistance of the p-type gallium nitride semiconductor can be made smaller. In addition, the smaller hydrogen concentration enables the reduction in the occurrence of the decline in performance, which is caused during the operation of the nitride semiconductor laser 11 and is attributable to hydrogen, and, for example, can prevent the applied voltage during an operation by energization from increasing.

A junction interface between the electrode 15 and the gallium nitride semiconductor surface (the surface 19) of the p-type gallium nitride semiconductor region is favorably inclined relative to a reference plane (for example, Sc) that is perpendicular to an axis extending in a direction of the c-axis (for example, Cx) of the p-type gallium nitride semiconductor region. According to this nitride semiconductor laser 11, when the hydrogen concentration N(H) of the p-type gallium nitride semiconductor providing the gallium nitride semiconductor surface is reduced so as to equal or fall below 10 percent of the p-type dopant concentration N(p) of the p-type gallium nitride semiconductor, the specific resistance can be reduced. For example, the specific resistance is 2.0 Ωcm or lower. In addition, a contact resistance between the p-type gallium nitride semiconductor and the electrode can also be reduced. For example, the contact resistance is 1e−3 Ωcm² or lower. In this case, “1e−3” and “1E−3” denote 1×10⁻³.

Magnesium, zinc, berylium, and the like can be used as the p-type dopant. A gallium nitride semiconductor grown using a material including hydrogen has the hydrogen that bonds to magnesium. Concentrations of magnesium and hydrogen in a semiconductor layer are measured by, for example, secondary ion mass spectrometry (SIMS). For example, magnesium is favorably used as the p-type dopant at a magnesium concentration of 1e18 cm⁻³ or higher and 1e19 cm⁻³ or lower. In addition, the reduced hydrogen concentration is, for example, 5e16 cm⁻³ or higher and 5e−17 cm⁻³ or lower. More specifically, for example, the magnesium concentration of the p-type cladding layer 23, which is made of InAlGaN, is 4e18 cm⁻³ or higher and 7e18 cm⁻³ or lower. For example, the reduced hydrogen concentration of the p-type cladding layer 23, which is made of InAlGaN, is 1e17 cm⁻³ or higher and 5e17 cm⁻³ or lower. For example, the magnesium concentration of the electron blocking layer 39 in the case of AlGaN is 1e18 cm⁻³ or higher and 3e18 cm⁻³ or lower. For example, the reduced hydrogen concentration of the electron blocking layer 39, which is made of AlGaN, is 5e18 cm⁻³ or higher and 8e18 cm⁻³ or lower.

In the nitride semiconductor laser device 11, the n-type cladding layer 21, the p-type cladding layer 23, and the emission layer 13 (the active layer 25) are mounted on the supporting base 17. The supporting base 17 has conductivity. For example, the conductivity has a value necessary for allowing current can be applied to the semiconductor laser 11 through the supporting base 17. The supporting base 17 includes a primary surface 17a comprising a semipolar semiconductor surface and a back surface 17b. The primary surface 17a is constituted by a gallium nitride semiconductor made of, for example, hexagonal system GaN. In a preferable example, the supporting base 17 comprises a hexagonal group III nitride based semiconductor and, furthermore, for example, a gallium nitride semiconductor. The primary surface 17a is inclined relative to a reference plane (for example, a representative c-plane “Sc”) that is perpendicular to a reference axis extending in a c-axis direction (a direction of a c-axis vector VC) of the gallium nitride semiconductor. In addition, the primary surface 17a has a semipolar nature. The semiconductor region 19 is provided on the primary surface 17a of the supporting base 17.

FIG. 1 shows an orthogonal coordinate system S and a crystal coordinate system CR. A normal axis NX is oriented in a direction of a Z-axis of the orthogonal coordinate system S. The primary surface 17a extends parallel to a predetermined plane that is defined by an X-axis and a Y-axis of the orthogonal coordinate system S. In addition, FIG. 1 shows a representative c-plane Sc. In the example shown in FIG. 1, the c-axis of the group III nitride semiconductor of the supporting base 17 inclines at an angle ALPHA in a direction from a c-axis to an m-axis of the group III nitride semiconductor with respect to the normal axis NX.

The n-type cladding layer 21, the light emitting layer 25, and the p-type cladding layer 23 are mounted in this order on the primary surface 17a. When the supporting base 17 is constituted by a group III nitride semiconductor, the semipolar nature of the primary surface 17a results from that of the group III nitride semiconductor of the supporting base 17. The n-type cladding layer 21, the active layer 25, and the p-type cladding layer 23 are arranged in the direction of the normal axis NX of the primary surface 17a. The primary surface 17a is inclined at an angle ALPHA of 63 degrees or more and less than 80 degrees with reference to the plane perpendicular to a reference axis Cx, which extends in the direction of a c-axis of the hexagonal nitride based semiconductor, toward the direction of an m-axis of a hexagonal system nitride semiconductor. The active layer 25 is provided between the n-type cladding layer 21 and the p-type cladding layer 23.

In the nitride semiconductor laser device 11, the n-type cladding layer 21 is composed of a nitride semiconductor including indium and aluminum as group III constituent elements, and the p-type cladding layer 23 is composed of a nitride semiconductor including indium and aluminum as group III constituent elements.

In addition, since the core semiconductor region or, in other words, the surface of the emission layer 13 has a semipolar nature in the angle range described above, the cladding layer 23 can be provided with a thick-film nitride semiconductor on the active layer 25 for the same reasons that the cladding layer 21 is provided with a thick film. Accordingly, the n-type cladding layer 21 is constituted by a thick-film first nitride semiconductor, and the p-type cladding layer 23 is constituted by a thick-film second nitride semiconductor.

The n-type cladding layer 21, the p-type cladding layer 23, and the active layer 25 are arranged in the direction of the normal axis NX of the semipolar primary surface 17a. The active layer 25 is provided so as to generate light having a peak wavelength within a wavelength range of 480 nm or more and 540 nm or less. The active layer 25 includes an epitaxial layer made of a gallium nitride semiconductor. The epitaxial layer is favorably made of ternary InGaN with an indium composition of 0.2 or higher. When the active layer 25 is provided on the semipolar surface that is inclined at an angle of 63 degrees or more and less than 80 degrees, step-flow growth resulting from the semipolar surface also technically contributes to InGaN growth. The active layer 25 may have a single quantum well structure or a multiple quantum well structure. When the active layer 25 has a quantum well structure, for example, the epitaxial layer can be a well layer 25a. The active layer 25 includes a barrier layer 25b constituted by a gallium nitride semiconductor, and the well layer 25a and the barrier layer 25b are alternately arranged. For example, the well layer 25a is made of InGaN or the like, and the barrier layer 25b is made of GaN, InGaN, or the like. The use of the semipolar base surface for the active layer 25 enables the semiconductor laser device 11 to emit light with a wavelength of 510 nm or more and 540 nm or less in a favorable manner. Preferable optical confinement and low drive current can be provided in this wavelength range.

With the group III nitride semiconductor laser device 11, the semiconductor region 19 includes a first end face 28a and a second end face 28b which intersect an m-n plane defined by the m-axis and the normal axis NX of the hexagonal system group III nitride semiconductor.

The group III nitride semiconductor laser 11 further comprises an insulating film 31. The insulating film 31 covers the surface 19a of the semiconductor region 19. The insulating film 31 includes an opening 31a which forms, for example, a striped pattern and extends in a direction of the line of intersection LIX of the surface 19a of the semiconductor region 19 and the m-n surface. The electrode 15 is in contact with the surface 19a of the semiconductor region 19 (for example, an Mg-doped p-type contact layer 33) via the opening 31a and extends in the direction of the intersection line LIX. In the group III nitride semiconductor laser 11, a laser waveguide includes the n-type cladding layer 21, the p-type cladding layer 23, and the active layer 25 (the emission layer 13) and extends in the direction of the intersection line LIX.

Referring to FIG. 1 again, the p-type contact layer 33 is provided so as to be joined to the p-type cladding layer 23, so that the electrode 15 is in contact with the p-type contact layer 33. For example, a thickness of the p-type contact layer 33 can be set to 50 nm or less and 10 nm or more. A thickness of the p-type cladding layer 23 is greater than the thickness of the contact layer 33 which is necessary for making preferable contact with the electrode 15. In addition, a p-type dopant concentration of the p-type contact layer 33 is favorably higher than a p-type dopant concentration of the p-type cladding layer 23. According to this structure, holes are supplied from the p-type contact layer 33 of a high dopant concentration to the p-type cladding layer 23 of a low dopant concentration, thereby contributing to the reduction in drive voltage. A refractive index of the p-type cladding layer 23 is favorably lower than a refractive index of the p-type contact layer 33. The insulating film 31 and the electrode 15 are provided on the p-type contact layer 33. The thick cladding layer 23 is capable of preventing optical loss caused by absorption of propagating light and the electrode. For example, an ohmic electrode to the p-type contact layer 33 can comprise Pd, Au, Ni, Pt, or the like.

With the group III nitride semiconductor laser 11, the first end surface 28a and the second end surface 28b intersect an m-n plane defined by the m-axis and the normal axis NX of the hexagonal system group III nitride semiconductor. A laser cavity of the group III nitride semiconductor laser device 11 includes the first and second end faces 28a and 28b, and a laser waveguide extends from one to the other of the first and second end faces 28a and 28b. The first and second end faces 28a and 28b can be configured so as to differ from conventional cleavage planes such as a c-plane, an m-plane, and an a-plane. According to the group III nitride semiconductor laser 11, the first and second end faces 28a and 28b which constitute the laser cavity intersect with the m-n plane. The laser waveguide extends in a direction of a line of intersection of the m-n plane with the semipolar plane 17a. The group III nitride semiconductor laser 11 includes a laser cavity that enables a low threshold current. As a result, with respect to emission of light by the active layer 25, an inter-band transition is selected which enables lasing at a low threshold.

In addition, as shown in FIG. 1, dielectric multilayers 43a and 43b can be provided on the first and second end faces 28a and 28b, respectively. End face coating can also be applied to the end faces 28a and 28b to enable adjustment of reflectance.

The group III nitride semiconductor laser device 11 includes an n-side optical guiding region 35 and a p-side optical guiding region 37. The n-side optical guiding region 35 can include one or more n-side optical guiding layers, and the p-side optical guiding region 37 can include one or more p-side optical guiding layers. For example, the n-side optical guiding region 35 includes a first n-side optical guiding layer 35a and a second n-side optical guiding layer 35b and is made of GaN, InGaN, or the like. For example, the p-side optical guiding layer 37 includes a first p-side optical guiding layer 37a, a second p-side optical guiding layer 37b, and a third p-side optical guiding layer 37c, and is made of GaN, InGaN, or the like. For example, the electron blocking layer 39 may be provided between the first p-side optical guiding layer 37a and the second p-side optical guiding layer 37b. The third p-side optical guiding layer 37c may be provided between the electron blocking layer 39 and the active layer 25.

More specifically, the first n-side optical guiding layer 35a can be a first GaN optical guiding layer provided between the n-type cladding layer 21 and the active layer 25, and the second n-side optical guiding layer 35b can be a first InGaN optical guiding layer provided between the first optical guiding layer 35a and the active layer 25. In addition, the first p-side optical guiding layer 37a can be a second GaN optical guiding layer provided between the p-type cladding layer 21 and the active layer 25, the second p-side optical guiding layer 37b can be a second InGaN optical guiding layer provided between the first p-side optical guiding layer 37a and the active layer 25, and the third p-side optical guiding layer 37c can be a third InGaN optical guiding layer provided between the second p-side optical guiding layer 37b and the active layer 25. When the optical guiding regions 35 and 37 provided between the active layer 25 and the respective cladding layers 21 and 23 include at least two layers (an InGaN layer and a GaN layer) with refractive indices that differ from one another, strain contained therein can be reduced and, at the same time, a reduction in a difference in refractive indices between the cladding and the core can be avoided.

If necessary, the electron blocking layer 39 can be applied such that the electron blocking layer 39 is provided between the p-type cladding layer 23 and the active layer 25. The primary surface 17a of the semipolar semiconductor can be made of GaN, and the electron blocking layer 39 can be made of GaN, AlGaN, or the like.

In the nitride semiconductor laser device 11, the first nitride semiconductor of the n-type cladding layer 21 favorably includes gallium as a group III constituent element. A material that comprises In, Al, and Ga as group III constituent elements can be applied to the first nitride semiconductor. In addition, the second nitride semiconductor of the p-type cladding layer 23 favorably includes gallium as a group III constituent element. A material that comprises In, Al, and Ga as group III constituent elements can be applied to the second nitride semiconductor.

When the nitride semiconductor laser device 11 contains the n-type cladding layer 21 and p-type cladding layer 23 both made of InAlGaN, the InAlGaN of the n-type cladding layer 21 and p-type cladding layer 23 allows adjustment in a degree of lattice misfit with the supporting base and reduction in the refractive index, whereby favorable optical confinement can be realized.

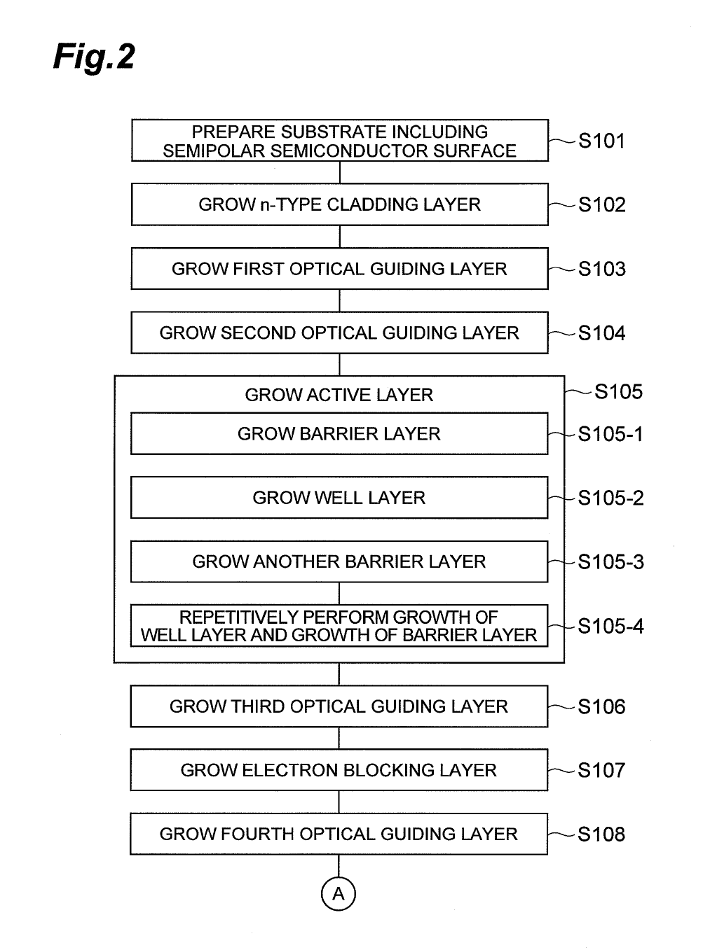

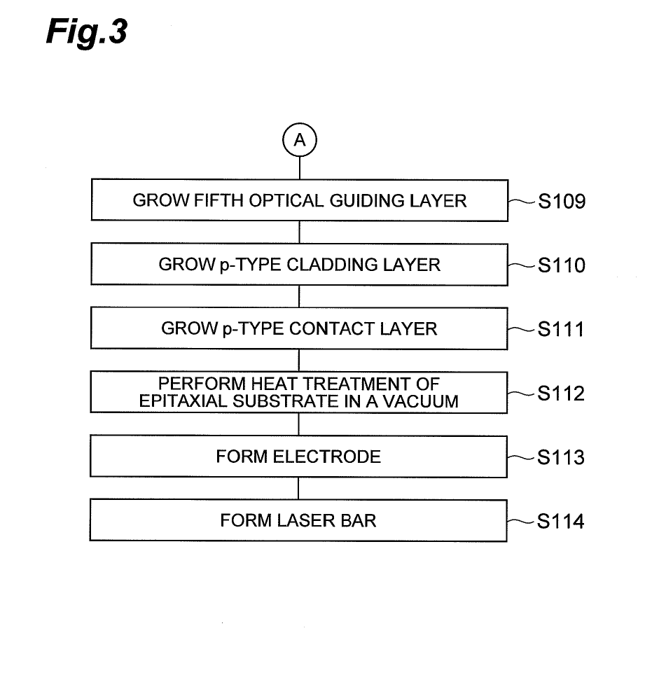

FIGS. 2 and 3 are diagrams showing primary steps of the method of fabricating a nitride semiconductor laser according to the present embodiment. A fabrication method for a nitride semiconductor laser will be described with reference to FIGS. 2 and 3. A laser diode is grown by metalorganic vapor deposition as described in the example below. When growing a gallium nitride semiconductor, a metalorganic group III material and a nitrogen material are supplied to a growth reactor. Trimethylgallium (TMGa), trimethylaluminum (TMAl), trimethylindium (TMIn), and ammonia (NH₃) are used as the material. In addition, silane (SiH₄), biscyclopentadienyl magnesium (Cp₂Mg), and the like are used as dopant materials. A gallium nitride semiconductor to be grown thereby can encompass GaN, InGaN, AlGaN, and InAlGaN. The p-type dopant favorably includes magnesium. Since biscyclopentadienyl magnesium (Cp₂Mg) is used as a material for the p-type dopant, the p-type dopant includes magnesium. In a gallium nitride semiconductor grown using a material including hydrogen (metalorganic group III material), the hydrogen bonds to magnesium. In addition, the gallium nitride semiconductor can be at least any of GaN, InGaN, AlGaN, and InAlGaN, and can further be In_{T}Al_{S}Ga_{1-S-T}N (0≦S≦1, 0≦T≦1).

In step S101, a substrate is prepared, which has a semiconductor surface made of a hexagonal system nitride semiconductor. The semiconductor surface has semipolar nature in which the semiconductor surface is inclined at an angle of 63 degrees or more and less than 80 degrees in the direction of an m-axis of the hexagonal nitride based semiconductor with reference to a plane perpendicular to a reference axis, which extends the direction of a c-axis of the hexagonal system nitride semiconductor. In a preferable example, the substrate is a gallium nitride semiconductor substrate and, for example, a GaN substrate can be used. The primary surface of the GaN substrate can be inclined in the direction of an m-axis of GaN at an angle of 75 degrees with reference to the plane that is perpendicular to a reference axis extending in the direction of a c-axis of the GaN semiconductor.

In step S102, an n-type cladding layer is grown on the semipolar semiconductor plane of the substrate. The thickness of the n-type cladding layer can be, for example, 2 μm or more. A refractive index of the n-type cladding layer is smaller than a refractive index of GaN. The n-type cladding layer is composed of a first nitride semiconductor including indium and aluminum as group III constituent elements. For example, Si-doped InAlGaN or Si-doped AlGaN can be used as the first nitride semiconductor. The primary surface of the n-type cladding layer has a semipolar nature to the semipolar semiconductor surface of the substrate. A growth temperature can be set to 800 degrees Celsius or higher and 950 degrees Celsius or lower, and is set to 870 degrees Celsius in the present example. When necessary, prior to growing the n-type cladding layer, an n-type buffer layer made of, for example, the same material as the semipolar semiconductor surface of the substrate can be grown on the semipolar semiconductor surface.

In step S103, after growing the n-type cladding layer, a first optical guiding layer is grown on a primary surface of the n-type cladding layer. For example, the first optical guiding layer can be GaN with a thickness of 50 nm or more and 500 nm or less. A primary surface of the first optical guiding layer has a semipolar nature similar to the semipolar semiconductor surface of the substrate. A growth temperature can be set to 800 degrees Celsius or higher and 1100 degrees Celsius or lower, and is set to 1050 degrees Celsius in the present example.

In step S104, after growing the first optical guiding layer, a second optical guiding layer is grown on a primary surface of the first GaN optical guiding layer. For example, the second optical guiding layer can be InGaN with a thickness of 50 nm or more and 250 nm or less. A primary surface of the second optical guiding layer has a semipolar nature similar to the semipolar semiconductor surface of the substrate. An indium composition of InGaN of the second optical guiding layer can be 0.01 or more and 0.05 or less. A growth temperature can be set to 800 degrees Celsius or higher and 900 degrees Celsius or lower, and is set to 840 degrees Celsius in the present example.

In step S105, after growing the optical guiding layers, an active layer is grown on the semipolar semiconductor surface. The active layer is structured so as to be capable of generating light having a peak wavelength within a wavelength range of 480 nm or more and 540 nm or less. For example, the active layer has any of a single quantum well structure, a multiple quantum well structure, a bulk structure, and the like. In the formation of the active layer having a quantum well structure, a well layer can be grown on the semipolar semiconductor surface after growing the optical guiding layers. Alternatively, after growing the optical guiding layers, in step S105-1, a barrier layer can be grown on the semipolar semiconductor surface, and subsequently, in step S105-2, a well layer can be grown on the barrier layer. Furthermore, in step S105-3, another barrier layer can be grown on the well layer. When necessary, in step S105-4, growth of a well layer and growth of a barrier layer can be repeated. For example, the well layer can be made of InGaN, and the barrier layer can be made of GaN or InGaN. Since indium must be incorporated at a composition of 0.20 or higher when growing a semiconductor of the active layer, a growth temperature of the well layer is favorably 800 degrees Celsius or lower, for example. In order to avoid thermal damage to the well layer which may be caused during the growth of the semiconductor for the active layer, a growth temperature of the barrier layer is favorably 900 degrees Celsius or lower, for example. An indium composition of InGaN of the well layer can be 0.2 or more and 0.4 or less. A primary surface of the active layer has a semipolar nature similar to the semipolar semiconductor surface of the substrate. A growth temperature of the well layer can be set to 670 degrees Celsius or higher and 780 degrees Celsius or lower. In the present example, In_{0.30}Ga_{0.70}N is grown at 720 degrees Celsius.

In step S106, after growing the active layer, a third optical guiding layer is grown on a primary surface of the active layer. For example, the third optical guiding layer can be InGaN with a thickness of 50 nm or more and 100 nm or less. For example, an indium composition of InGaN of the third optical guiding layer can be 0.01 or more and 0.05 or less. A primary surface of the third optical guiding layer has a semipolar nature similar to the semipolar semiconductor surface of the substrate. A growth temperature can be set to 800 degrees Celsius or higher and 900 degrees Celsius or lower, and is set to 840 degrees Celsius in the present example.

In step S107, after growing the third optical guiding layer, an electron blocking layer can be grown thereon. The electron blocking layer is favorably made of GaN or AlGaN. When the electron blocking layer is made of GaN, a growth temperature of the electron blocking layer can be set lower than that of AlGaN growth. A primary surface of the electron blocking layer has a semipolar nature similar to the semipolar semiconductor surface of the substrate. A growth temperature can be set to 800 degrees Celsius or higher and 900 degrees Celsius or lower, and is set to 900 degrees Celsius in the present example.

In step S108, after growing the electron blocking layer, a fourth optical guiding layer is grown on a primary surface of the electron blocking layer. For example, the fourth optical guiding layer can be InGaN with a thickness of 50 nm or more and 250 nm or less. For example, an indium composition of InGaN of the fourth optical guiding layer can be 0.01 or more and 0.05 or less. A primary surface of the fourth optical guiding layer has a semipolar nature similar to the semipolar semiconductor surface of the substrate. The electron blocking layer is sandwiched between two InGaN layers and joined thereto. A growth temperature can be set to 800 degrees Celsius or higher and 900 degrees Celsius or lower, and is set to 840 degrees Celsius in the present example.

In step S109, after growing the fourth optical guiding layer, a fifth optical guiding layer is grown on a primary surface of the fourth optical guiding layer. The fifth optical guiding layer can be Mg-doped GaN. For example, the fifth optical guiding layer can be GaN with a thickness of 50 nm or more and 500 nm or less. A primary surface of the fifth optical guiding layer has a semipolar nature similar to the semipolar semiconductor surface of the substrate. A growth temperature can be set to 800 degrees Celsius or higher and 950 degrees Celsius or lower, and is set to 840 degrees Celsius in the present example.

In step S110, after growing the optical guiding layers, a p-type cladding layer with a thickness of 500 nm or more is grown on the semipolar semiconductor surface. A refractive index of the p-type cladding layer is smaller than a refractive index of GaN. The p-type cladding layer is composed of a second nitride semiconductor including indium and aluminum as group III constituent elements. For example, Mg-doped. InAlGaN and/or Mg-doped AlGaN can be used as the second nitride semiconductor. A primary surface of the p-type cladding layer has a semipolar nature similar to the semipolar semiconductor surface of the substrate. A growth temperature can be set to 800 degrees Celsius or higher and 950 degrees Celsius or lower, and is set to 870 degrees Celsius in the present example.

In step S111, after growing the p-type cladding layer, a p-type contact layer is grown on a primary surface of the p-type cladding layer. A primary surface of the p-type contact layer has a semipolar similar to the semipolar semiconductor surface of the substrate. For example, the p-type contact layer can be made of Mg-doped GaN, Mg-doped InGaN, Mg-doped AlGaN, or Mg-doped InAlGaN. A growth temperature of Mg-doped GaN can be set to 800 degrees Celsius or higher and 950 degrees Celsius or lower, and is set to 900 degrees Celsius in the present example.

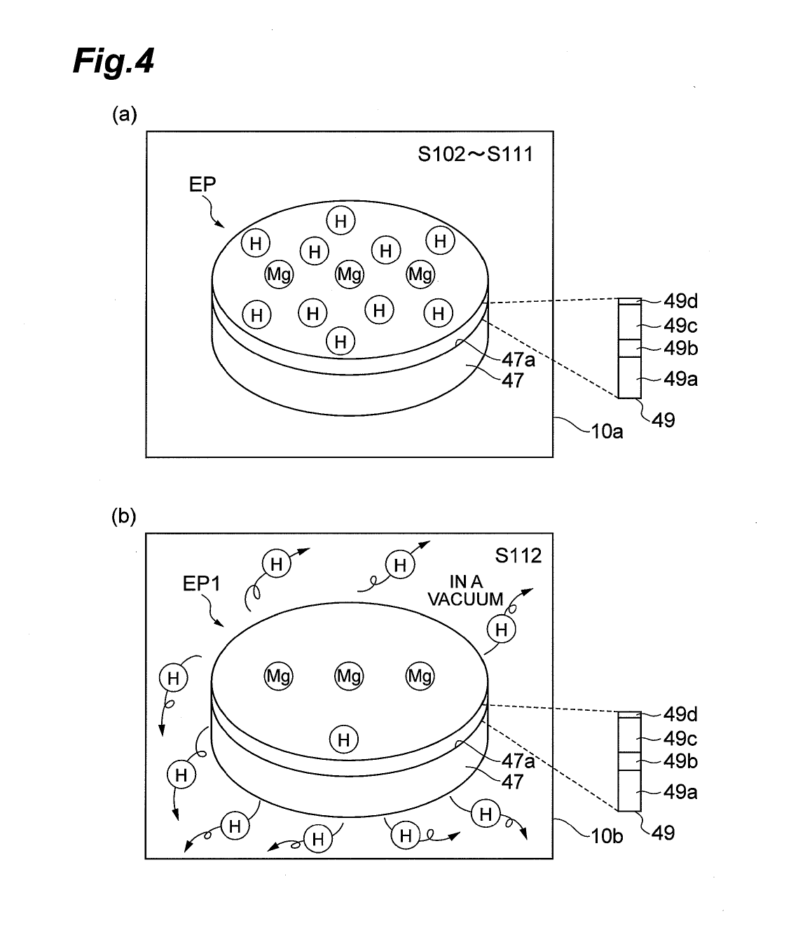

As shown in Part (a) of FIG. 4, the epitaxial substrate EP is fabricated in a growth reactor 10a through steps S102 to S111 described above. The epitaxial substrate EP includes a substrate 47 and a semiconductor laminate 49 provided on a primary surface 47a of the substrate 47. The semiconductor laminate 49 includes an n-type group III nitride semiconductor region 49a, an emission layer 49b, a p-type group III nitride semiconductor region 49c, and an n-type group III nitride semiconductor contact layer 49d. After the aforementioned series of growth steps for growing the semiconductor laminate 49, the epitaxial substrate is taken out of the growth reactor 10a. The epitaxial substrate EP comprises a p-type group III nitride semiconductor region including a series of p-type semiconductor layers grown as described above. The p-type group III nitride semiconductor region contains a p-type dopant and hydrogen. A large portion of p-type dopant atoms therein is chemically bonded to hydrogen and has not been activated. In the present example, a heat treatment for activating the p-type group III nitride semiconductor region is performed. The p-type group III nitride semiconductor region includes a group III nitride semiconductor surface (a so-called semipolar surface) that is inclined relative to a reference plane perpendicular to an axis extending in a direction of a c-axis of the gallium nitride semiconductor. In addition, in this example, a surface of the group III nitride semiconductor layer formed on the semipolar surface of the substrate inherits a plane orientation of the substrate as a base, and becomes a semipolar surface. In the heat treatment for activation, the semipolar surface exhibits characteristics that differ from those of a c-plane.

In step S112, the heat treatment of the group III nitride semiconductor region of the epitaxial substrate is performed in a vacuum. According to this fabrication method, the gallium nitride semiconductor includes a p-type dopant, and the gallium nitride semiconductor is included in the group III nitride semiconductor region. The heat treatment of the group III nitride semiconductor region and the group III nitride semiconductor surface is performed in a vacuum, so that activation of the p-type dopant in the gallium nitride semiconductor of the semiconductors occurs. In addition, as compared to a heat treatment in a nitrogen atmosphere, the heat treatment in a vacuum enables greater hydrogen desorption in a very shorter period of time for the heat treatment. As a result, a decline in quality of the group III nitride semiconductor surface is reduced.

As shown in Part (b) of FIG. 4, the heat treatment for activation can be performed in an apparatus 10b that differs from the growth reactor 10a. The apparatus 10b for the heat treatment includes a chamber capable of achieving a pressure that is lower than a pressure used for film formation. For example, a chamber for molecular beam epitaxy (MBE) or the like can be used for the heat treatment for this activation. In such a case, after taking out the epitaxial substrate EP from the growth reactor 10a, the epitaxial substrate EP is loaded into the activation treatment apparatus 10b. After the heat treatment, the activated epitaxial substrate EP1 can be taken out from the heat treatment apparatus 10b.

For the heat treatment for activation, for example, a degree of vacuum of 1×10⁻⁵ Torr (1.33322×10⁻³ pascal) or lower is favorably maintained. In the present example, an anode electrode is formed after the heat treatment. Even when an anode electrode is formed on the group III nitride semiconductor surface after the heat treatment in a vacuum, deterioration of contact resistance of the anode electrode can be avoided.

The temperature of the heat treatment for activation is favorably set to 650 degrees Celsius or higher. A heat treatment at 650 degrees Celsius or higher can provide a relatively high hydrogen desorption rate. In addition, the temperature is favorably set to 700 degrees Celsius or lower. A heat treatment at 700 degrees Celsius or lower is capable of reducing desorption of nitrogen from the group III nitride semiconductor surface. In this case, when the heat treatment is performed while maintaining a degree of vacuum of 1×10⁻⁵ Torr (1.33322×10⁻³ pascal) or lower, the heat treatment time is favorably set to 1 minute or more and 30 minutes or less in order to obtain a desired hydrogen release. As a result, both a sheet resistance of 2.0 Ωcm or less and a contact resistance of 1.0e−3 Ωcm² or less can be also achieved. For example, the degree of vacuum of the heat treatment is favorably 1×10⁻⁶ Torr or less, more favorably 1×10⁻⁷ Torr or less, and even more favorably 1×10⁻⁸ Torr or less.

According to findings compiled by the present inventors, when the semipolar surface that is exposed to a vacuum during a heat treatment is inclined in a direction from the c-axis to the m-axis of the group III nitride that has the semipolar surface, and the angle of inclination is 63 degrees or more and less than 80 degrees, the semipolar surface particularly exhibits characteristics that differ from those of the c-plane. Such a semipolar surface, unlike a c-plane constituted by an array of gallium atoms or an array of nitrogen atoms, includes an arrangement of both gallium atoms and nitrogen atoms. Both gallium atoms and nitrogen atoms appear on the top surface tilted at an angle in an angle range of 63 degrees or more and less than 80 degrees to form an atomic arrangement. Therefore, a plane orientation at an angle of 63 degrees or more and less than 80 degrees is more sensitive to desorption of nitrogen from a group III nitride semiconductor surface as compared to a group III nitride semiconductor surface, such as polar planes including a c-plane.

By adopting activation according to the present embodiment, an active layer can be provided so as to emit light in a wavelength range of 480 nm or more and 540 nm or less, and a laser diode which emits light in a green wavelength or nearby wavelengths can be fabricated. In addition, an active layer can be provided so as to emit light in a wavelength range of 510 nm or more and 540 nm or less. In this case, a laser diode which emits light in a green wavelength region can be fabricated.

A p-type gallium nitride semiconductor prior to a heat treatment for activation includes a p-type dopant and hydrogen, and a p-type gallium nitride semiconductor after the heat treatment for activation also includes a p-type dopant and hydrogen. However, a hydrogen concentration of a p-type gallium nitride semiconductor subjected to activation is reduced, so that the hydrogen concentration is equal to or less than 10 percent of the p-type dopant concentration of the p-type gallium nitride semiconductor. The heat treatment in a vacuum promotes the desorption of hydrogen from the p-type gallium nitride semiconductor and, as a result, the hydrogen concentration of the p-type gallium nitride semiconductor can be reduced so as to equal or fall below 10 percent of the p-type dopant concentration of the p-type gallium nitride semiconductor.

With growth using a metalorganic group III material, hydrogen included in the metalorganic group III material remains in a gallium nitride semiconductor. However, according to an experiment conducted by the present inventors, a degree of vacuum used for the heat treatment in a vacuum is favorably 7.5×10⁻⁸ Torr or lower. In a degree of vacuum of 7.5×10⁻⁸ Torr (1×10⁻⁵ Pascal) or lower or, in other words, under an ultrahigh vacuum, activation of the gallium nitride semiconductor is promoted.

According to this fabrication method, a gallium nitride semiconductor grown so as to be included in a group III nitride semiconductor region includes a p-type dopant and hydrogen. When the heat treatment of the group III nitride semiconductor region is performed in a vacuum, the activation of dopant that the gallium nitride semiconductor contains occurs in the semiconductors. In addition, the heat treatment in a vacuum enables greater hydrogen desorption during the heat treatment as compared to heat treatment in a nitrogen atmosphere.

According to this group III nitride semiconductor device, when the hydrogen concentration of the p-type gallium nitride semiconductor that provides the gallium nitride semiconductor surface is reduced so as to equal to or fall below 10 percent of the p-type dopant concentration of the p-type gallium nitride semiconductor, a contact resistance of the p-type gallium nitride semiconductor can also be reduced.

In step S113, the anode electrode is formed on the p-type contact layer, and a cathode electrode is formed on a back plane of the substrate to form a substrate product. According to the above-described dopant activation, since the activation is performed using a heat treatment in a vacuum, a light-emitting device with a low contact resistance is provided in addition to a p-type gallium nitride semiconductor having a low specific resistance. In step S114, the substrate product is cut in a length of the laser cavity to fabricate a laser bar.

In addition, since a heat treatment in a vacuum (in particular, in an ultrahigh vacuum) enables the reduction of the time required to achieve desired activation, the heat treatment can reduce a decline in quality of a group III nitride semiconductor surface as compared to a heat treatment in a nitrogen atmosphere. Therefore, when forming an anode electrode so as to be in contact with a group III nitride semiconductor surface that has been subjected to activation, the contact resistance falls to 5e−4 Ωcm² or lower. This value is superior in comparison to a contact resistance of 1e−3 Ωcm² when forming an anode electrode in contact with a group III nitride semiconductor surface subjected to other activation treatments.

### FIRST EXAMPLE

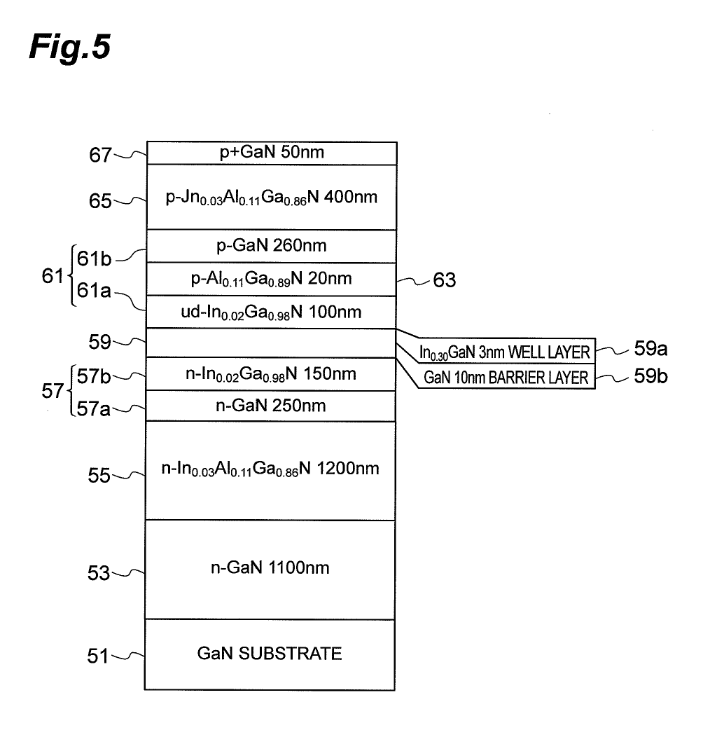

FIG. 5 is a diagram schematically showing a structure of a group III nitride semiconductor laser fabricated in a first example.

A group III nitride substrate is prepared which has a semipolar primary surface. In the present example, a GaN substrate 51 having a semipolar primary is prepared, and the primary surface is inclined at an angle of 75 degrees relative to an m-axis direction. The plane orientation of the semipolar primary surface corresponds to a {20-21 } plane. A semiconductor region having an LD structure LD1 that operates in a lasing wavelength band of 525 nm is grown on the semipolar primary surface of the GaN substrate 51. After placing the GaN substrate 51 in a growth reactor, pretreatment (thermal cleaning) of the GaN substrate is performed. The pretreatment is performed under conditions including an atmosphere including ammonia and hydrogen, a heat treatment temperature of 1050 degrees Celsius, and a treatment time of 10 minutes.

After the pretreatment, a gallium nitride semiconductor layer, such as an n-type gallium nitride layer 53, is grown on the GaN substrate 51 at a growth temperature of 950 degrees Celsius. The n-type GaN layer has a thickness of, for example, 1100 nm. An n-type cladding layer is grown on the gallium nitride semiconductor layer. An n-type cladding layer 55 includes, for example, an InAlGaN (In composition 0.03, Al composition 0.11, and Ga composition 0.86) layer grown at a growth temperature of 900 degrees Celsius. The n-type cladding layer 55 has a thickness of, for example, 1.2 μm. The n-type InAlGaN layer is strained. In the present example, an n-side optical guiding layer includes, for example, an n-type GaN layer 57a grown at a growth temperature of 1000 degrees Celsius and an undoped InGaN layer 57b grown at a growth temperature of 870 degrees Celsius. The InGaN layer 57b has a thickness of, for example, 150 nm. The n-type GaN layer 57a has a thickness of, for example, 250 nm.

An active layer is grown on an n-side optical guiding layer 57. The active layer 59 includes a well layer 59a. In the present example, the well layer 59a includes, for example, an In_{0.3}Ga_{0.7}N (In composition 0.30, Ga composition 0.70) layer grown at a growth temperature of 720 degrees Celsius. The InGaN layer has a thickness of, for example, 3 nm. The InGaN layer is compressively strained. When necessary, the active layer 59 can also include, for example, a barrier layer 59b. For example, the barrier layer 59b includes a GaN layer which is grown at a growth temperature of 840 degrees Celsius and which has a thickness of 10 nm. In the present example, the active layer 59 has a double quantum well structure.

A p-side optical guiding layer and an electron blocking layer are grown on the active layer 59. In the present example, a p-side optical guiding layer 61 includes, for example, an undoped InGaN layer 61a which is grown at a growth temperature of 870 degrees Celsius and which has an indium composition of 0.02. The p-side InGaN layer 61a has a thickness of, for example, 100 nm. The p-side InGaN layer 61a is strained. An electron blocking layer is grown on the p-side optical guiding layer 61a. In the present example, the electron blocking layer includes, for example, a p-type AlGaN layer 63 which is grown at a growth temperature of 890 degrees Celsius and which has an aluminum composition of 0.11. The AlGaN layer 63 has a thickness of, for example, 20 nm. Another p-side optical guiding layer is grown on the electron blocking layer. This p-side optical guiding layer includes, for example, a p-type GaN layer 61b grown at a growth temperature of 840 degrees Celsius. The p-side GaN layer has a thickness of, for example, 260 nm.

A p-type cladding layer is grown on the p-side optical guiding layer. The p-type cladding layer includes, for example, an InAlGaN (In composition 0.03, Al composition 0.11, and Ga composition 0.86) layer 65 that is grown at a growth temperature of 880 degrees Celsius. The p-type cladding layer has a thickness of, for example, 400 nm. The p-type InAlGaN layer 65 is also strained.

A p-type contact layer is grown on the p-type cladding layer. In the present example, the p-type contact layer includes, for example, a GaN layer 67 grown at a growth temperature of 880 degrees Celsius. The p-type contact layer has a thickness of, for example, 50 nm. As a result of these processes, an epitaxial substrate is fabricated.

A heat treatment of the epitaxial substrate is performed in a vacuum. After this heat treatment, a Pd electrode with a striped pattern is formed on the heat-treated p-type contact layer and a Ti/Al electrode is formed on a back surface (a back side that may be polished as necessary) of the GaN substrate. Gold is used as a material of a pad electrode. This laser diode has a lasing wavelength of 525 nm.

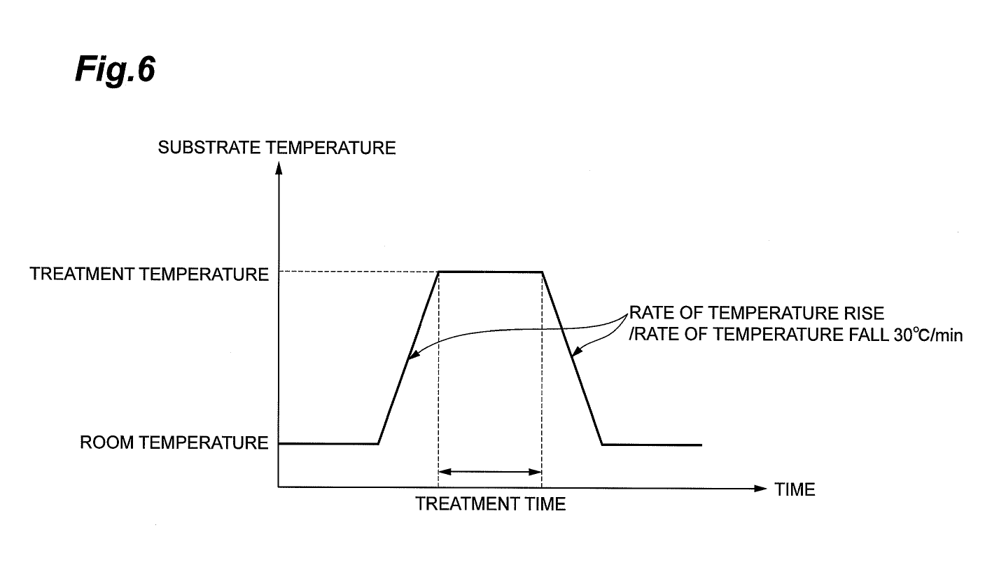

The grown epitaxial substrate with a laser structure is subjected to a heat treatment in a heat treatment apparatus at varying degrees of vacuum, temperatures, and treatment times. The heat treatment apparatus comprises a cryopump and a liquid nitrogen shroud, and is capable of achieving a degree of vacuum of 1×10⁻¹¹ Torr (1.33322×10⁻⁹) or lower. The degree of vacuum of the heat treatment apparatus is measured using an ionization vacuum gauge. For the measurement of the heat treatment temperature, a substrate temperature is measured using a radiation thermometer. FIG. 6 is a diagram showing an example of a temperature profile of a heat treatment according to an embodiment. In the temperature profile, a rate of temperature rise is +30 degrees/min. and a rate of temperature fall is −30 degrees/min. In the temperature variation, the temperature starts from room temperature (for example, 25 degrees Celsius) to a target temperature and is maintained at the target temperature for a desired period of time. Subsequently, the temperature is lowered from the target temperature to room temperature. After the heat treatment, the epitaxial substrate having been returned to room temperature atmosphere is taken out of the heat treatment apparatus.

### SECOND EXAMPLE

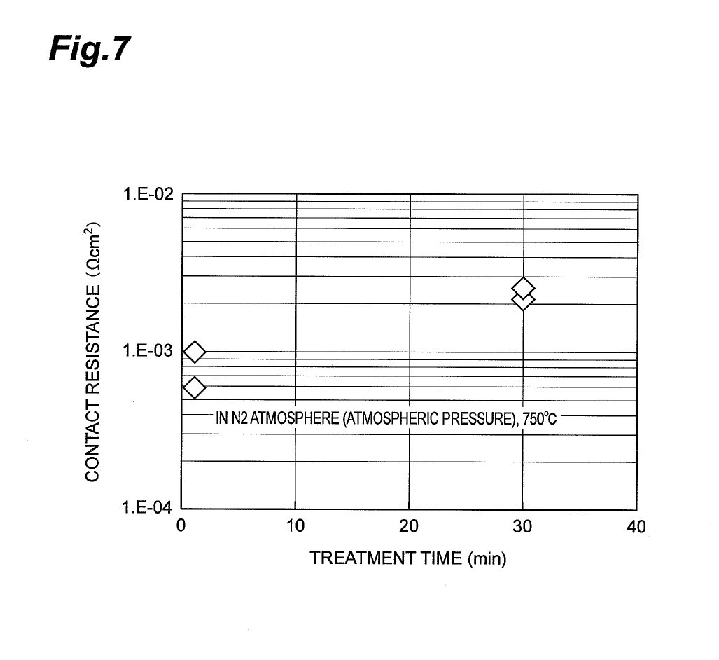

FIG. 7 is a diagram showing a relationship between heat treatment time and contact resistance. The heat treatment is performed in a nitrogen atmosphere (atmospheric pressure) at 750 degrees Celsius. Contact resistance and specific resistance in the description below are measured by the transfer length measurement (TLM) method. Referring to FIG. 7, as heat treatment time increases, a contact resistance between the anode electrode and the p-type contact layer tends to increase. In other words, when performing a heat treatment on an epitaxial substrate including a p-type gallium nitride semiconductor which is semipolar and which has a laser structure, the heat treatment performed over a long period of time induces detachment of nitrogen atoms from the surface and, as a result, increases the contact resistance. Therefore, the heat treatment for activation is desirably performed for a short period of time. In particular, unlike a polar substrate, since the surface atom arrangement of a semipolar substrate includes both gallium atoms and nitrogen atoms, heat treatment under atmospheric pressure is more likely to cause atoms of nitrogen exhibiting high vapor pressure to detach from the surface to form vacancies. Due to such detachment, the contact resistance deteriorates. The activation of an epitaxial substrate including a semipolar surface is favorably performed over a short period of time.

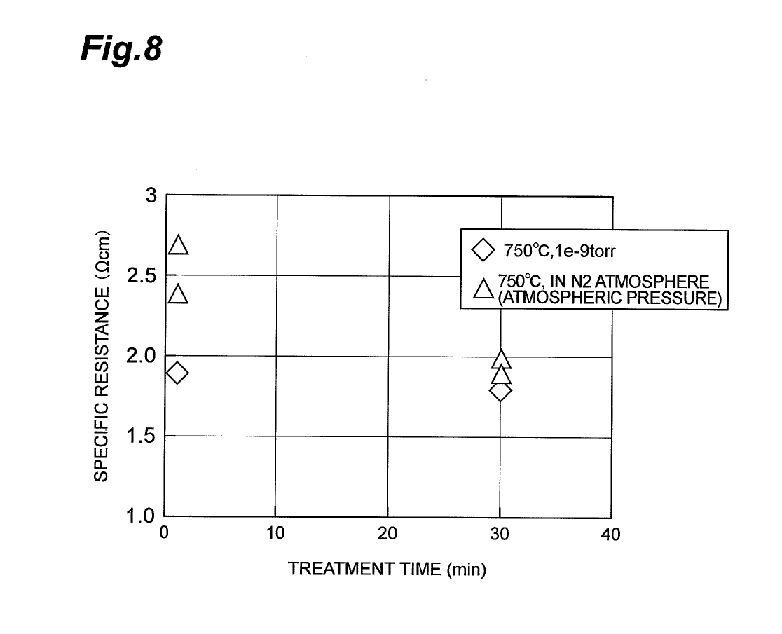

FIG. 8 is a diagram showing a relationship between heat treatment time and specific resistance of a p-type semiconductor layer. In order to achieve both low contact resistance and low specific resistance in a nitride semiconductor device fabricated on a semipolar substrate, the contact resistance must be maintained around 1×10⁻⁴ Ω·cm². The present inventors have examined methods that enable a heat treatment performed over a short period of time while maintaining a contact resistance of around 1×10⁻⁴ Ω·cm². With a heat treatment performed under atmospheric pressure (for example, a heat treatment in a nitrogen atmosphere under atmospheric pressure), as depicted by “outline triangles”, a specific resistance of a p-type GaN layer after a short period of time (for example, 1 minute) is around 2.5 Ω·cm and the specific resistance of the p-type GaN layer after a long period of time (for example, 30 minutes) is around 2.0 Ω·cm. However, as shown in FIG. 7, a heat treatment performed over a long period of time (30 minutes) is unable to provide a desired contact resistance. Conversely, a heat treatment which is performed over a short period of time and which is capable of providing a desired contact resistance is unable to realize a desired specific resistance in a p-type GaN layer. In other words, with a heat treatment time capable of achieving the contact resistance described above, activation is insufficient and a low specific resistance cannot be obtained.

On the other hand, a heat treatment in an high vacuum (1×10⁻⁹ Torr (1.33322×10⁻⁷ pascal), 750 degrees Celsius) is capable of realizing low specific resistance even when performed for a short period of time (for example, 1 minute), and is also capable of realizing a low specific resistance even when performed for a long period of time (30 minute). As depicted by “black squares”, a heat treatment in a vacuum enables diffusion and desorption of hydrogen atoms in the p-type GaN layer regardless of the treatment time. It is noteworthy that a low specific resistance can be realized by a heat treatment in a vacuum which is only performed for a short period of time. Moreover, the specific resistance prior to the heat treatment is high at 10 Ωcm or more.

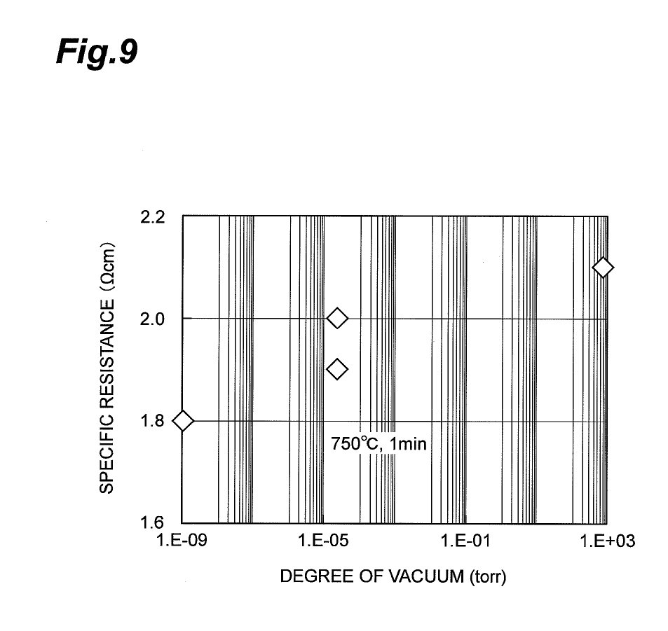

FIG. 9 is a diagram showing a relationship between a degree of vacuum and a p-type GaN layer in a heat treatment. This heat treatment is performed at a temperature of 750 degrees Celsius for a treatment time of 1 minute. The specific resistance prior to the heat treatment is high at 10 Ωcm or more, and a heat treatment performed under atmospheric pressure (nitrogen atmosphere) results in a specific resistance of 2.1 Ωcm. In FIG. 9, a heat treatment at a degree of vacuum of 2.3×10⁻⁵ Torr results in a specific resistance of 1.9 to 2.0 Ωcm, which means that the specific resistance can be reduced by around 10 percent as compared to the specific resistance for a heat treatment under atmospheric pressure. Therefore, a degree of vacuum of 1×10⁻⁵ Torr or lower enables a reduction in the specific resistance. In addition, a heat treatment at a degree of vacuum of 1×10⁻⁹ Torr results in a specific resistance of 1.8 Ωcm, which means that the specific resistance can be reduced by around 10 percent or more as compared to the specific resistance for a heat treatment under atmospheric pressure. With a degree of vacuum of around 1×10⁻⁹ Torr, besides enabling a reduction in the specific resistance, a hydrogen concentration in a p-type GaN layer during a heat treatment in an ultrahigh vacuum (a degree of vacuum of around 1×10⁻⁹ Torr) is reduced such that a ratio of the hydrogen concentration to a magnesium concentration of a p-type dopant (H concentration/Mg concentration) falls to or below 0.05. On the other hand, regarding a hydrogen concentration in a p-type GaN layer during a heat treatment under atmospheric pressure, a ratio of the hydrogen concentration to the magnesium concentration of a p-type dopant (H concentration/Mg concentration) is around 0.5. For example, a degree of vacuum capable of realizing a ratio of the hydrogen concentration to the magnesium concentration of a p-type dopant (H concentration/Mg concentration) of 0.1 or lower is around 1×10⁻⁸ Torr or lower.

In addition to the experiments described above, the present inventors have performed various experiments. These experiments and as already shown in FIGS. 7 and 8 teach that, in the plane orientation of a gallium nitride semiconductor (the range of an inclination angle of the c-axis) that is relatively resistant to long heat treatment times, the time of heat treatment can be determined based on characteristics and factors other than surface damage. The results in FIG. 8 teach that a heat treatment in a vacuum is capable of achieving a specific resistance of 2 Ω·cm or lower when performed for both short and long periods of time.

Regarding the plane orientation of a gallium nitride semiconductor that is relatively sensitive to long heat treatment times, the heat treatment time can be determined based on, for example, contact resistance characteristics. With a semipolar surface that is inclined at an angle of 63 degrees or more and less than 80 degrees in a direction from the c-axis to the m-axis of the group III nitride that has the semipolar surface, examples of degrees of vacuum of heat treatment and heat treatment times capable of realizing a desired contact resistance (for example, a contact resistance of 5e−4 Ωcm²) are as listed below.

Degree of vacuum (Torr), upper limit of heat treatment time.

| | | |
|---|---|---|
| 1 × 10⁻⁵, | 30 | minutes. |
| 1 × 10⁻⁶, | 10 | minutes. |
| 1 × 10⁻⁷, | 5 | minutes. |
| 1 × 10⁻⁸, | 2 | minutes. |
| 1 × 10⁻⁹, | 1 | minute. |

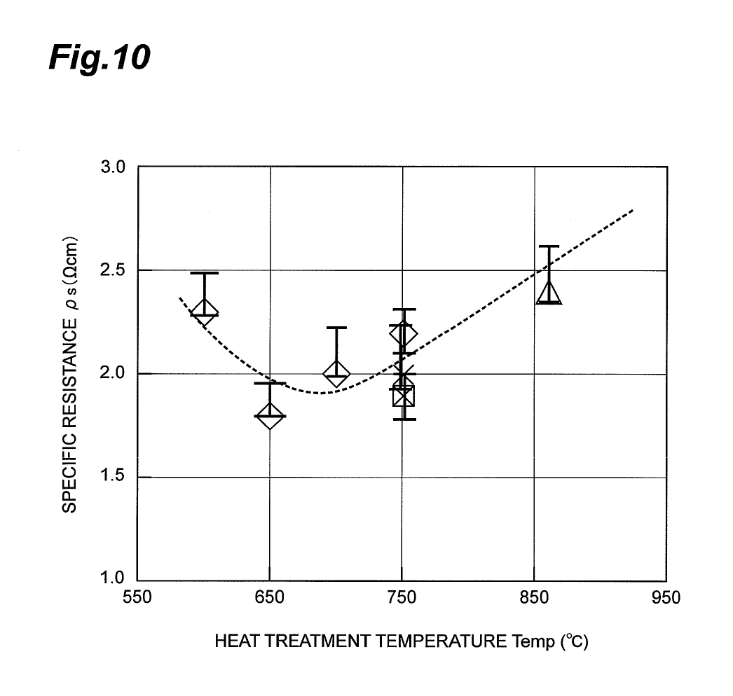

FIG. 10 is a diagram showing a relationship between heat treatment temperature and specific resistance. A temperature in which specific resistance is reduced to 2.0 Ωcm or lower falls within a heat treatment temperature range that is favorably 600 degrees Celsius or higher and 750 degrees Celsius or lower. In addition, an extremely low specific resistance can be realized in a heat treatment temperature range of 650 degrees Celsius or higher and 750 degrees Celsius or lower.

The present embodiment can provide a method of fabricating a gallium nitride semiconductor which enables activation of a p-type dopant with a heat treatment performed for a relatively short period of time. In addition, the present embodiment can provide a method of fabricating a group III nitride semiconductor device which enables activation of a p-type dopant with a heat treatment performed for a relatively short period of time. Furthermore, to the present embodiment can provide a group III nitride semiconductor device having a low layer resistance due to activation of a p-type dopant.

Having described and illustrated the principle of the invention in a preferred embodiment thereof, it is appreciated by those having skill in the art that the invention can be modified in arrangement and detail without departing from such principles. We therefore claim all modifications and variations coming within the spirit and scope of the following claims.

What is claimed is:

1. A method of fabricating a gallium nitride semiconductor of p-type conductivity, comprising the step of:
performing, in a vacuum, a heat treatment of a group III nitride semiconductor region, the group III nitride semiconductor region comprising a gallium nitride semiconductor, the gallium nitride semiconductor including a p-type dopant, the a group III nitride semiconductor region having a group III nitride semiconductor surface, the group III nitride semiconductor surface being inclined with respect to a reference plane perpendicular to a reference axis, and the reference axis extending in a direction of a c-axis of the gallium nitride semiconductor.

2. The method of fabricating a gallium nitride semiconductor according to claim 1, further comprising the step of preparing a substrate having a semipolar surface of a hexagonal group III nitride, the group III nitride semiconductor region being provided on the semipolar surface of the substrate.

3. The method of fabricating a gallium nitride semiconductor according to claim 1, wherein a degree of vacuum in the heat treatment is equal to or lower than 1×10⁻⁵ Torr.

4. The method of fabricating a gallium nitride semiconductor according to claim 1, wherein a degree of vacuum of the heat treatment is equal to or lower than 7.5×10⁻⁸ Torr.

5. The method of fabricating a gallium nitride semiconductor according to claim 1, wherein the heat treatment is performed at a temperature equal to or higher than 650 degrees Celsius.

6. The method of fabricating a gallium nitride semiconductor according to claim 1, wherein the heat treatment is performed at a temperature equal to or lower than 700 degrees Celsius.

7. The method of fabricating a gallium nitride semiconductor according to claim 1, wherein
the group III nitride semiconductor surface includes a semipolar plane, and the semipolar plane is inclined in a direction from a c-axis of a group III nitride of the group III nitride semiconductor region to an m-axis of the group III nitride, and
an angle of the inclination is 63 degrees or more and less than 80 degrees.

8. The method of fabricating a gallium nitride semiconductor according to claim 1, further comprising the step of supplying a dopant material for a p-type dopant, a metalorganic group III material, and a nitrogen material to a growth reactor to grow the gallium nitride semiconductor so as to form the group III nitride semiconductor surface.

9. The method of fabricating a gallium nitride semiconductor according to claim 1, wherein the p-type dopant includes magnesium.

10. The method of fabricating a gallium nitride semiconductor according to claim 1, wherein the gallium nitride semiconductor comprises any of GaN, InGaN, AlGaN, and InAlGaN.

11. The method of fabricating a gallium nitride semiconductor according to claim 1, further comprising the step of forming an electrode on the group III nitride semiconductor surface.

12. A method of fabricating a group III nitride semiconductor device including a gallium nitride semiconductor of p-type conductivity, comprising the steps of:
performing, in a vacuum, a heat treatment of a group III nitride semiconductor region, the group III nitride semiconductor region comprising a gallium nitride semiconductor, the gallium nitride semiconductor including a p-type dopant, the group III nitride semiconductor region having a group III nitride semiconductor surface, the group III nitride semiconductor surface being inclined with respect to a reference plane perpendicular to a reference axis, and the reference axis extending in a direction of a c-axis of the gallium nitride semiconductor; and
forming an electrode on the group III nitride semiconductor surface.

13. The method of fabricating a group III nitride semiconductor device according to claim 12, further comprising the step of preparing a substrate, the substrate having a semipolar surface of a hexagonal group III nitride,
wherein the group III nitride semiconductor region is provided on the semipolar surface of the substrate.

14. The method of fabricating a group III nitride semiconductor device according to claim 12, wherein the formation of the electrode is performed after the heat treatment.

15. The method of fabricating a group III nitride semiconductor device according to claim 12, wherein a degree of vacuum in the heat treatment is equal to or lower than 1×10⁻⁵ Torr.

16. The method of fabricating a group III nitride semiconductor device according to claim 12, wherein a degree of vacuum in the heat treatment is equal to or lower than 7.5×10⁻⁸ Torr.

17. The method of fabricating a group III nitride semiconductor device according to claim 12, wherein the heat treatment is performed in a temperature range of 650 degrees Celsius or higher and 700 degrees Celsius or lower.

18. The method of fabricating a group III nitride semiconductor device according to claim 12, wherein
the group III nitride semiconductor surface includes a semipolar surface inclined in a direction from a c-axis of a group III nitride of the group III nitride semiconductor region to an m-axis of the group III nitride, and
an angle range of the inclination is 63 degrees or more and less than 80 degrees

19. The method of fabricating a group III nitride semiconductor device according to claim 12, further comprising the step of supplying a dopant material for a p-type dopant, a metalorganic group III material, and a nitrogen material to a growth reactor to grow the gallium nitride semiconductor,
wherein the heat treatment is performed by an apparatus that differs from the growth reactor, and
the apparatus includes a chamber capable of achieving pressure that is lower than pressure used for the growth.

20. The method of fabricating a group III nitride semiconductor device according to claim 12, further comprising the step of supplying, prior to the heat treatment, a metalorganic group III material and a nitrogen material to a growth reactor to grow an active layer constituted by a gallium nitride semiconductor, wherein
the group III nitride semiconductor region includes the active layer.

21. The method of fabricating a group III nitride semiconductor device according to claim 20, wherein the active layer is provided so as to emit light having a wavelength in a range of 480 nm or more and 540 nm or less.

22. The method of fabricating a group III nitride semiconductor device according to claim 20, wherein the active layer is provided so as to generate light having a wavelength in a range of 510 nm or more and 540 nm or less.

23. The method of fabricating a group III nitride semiconductor device according to claim 12, wherein
the group III nitride semiconductor surface comprises a p-type gallium nitride semiconductor,
the p-type gallium nitride semiconductor includes a p-type dopant and hydrogen, and
a hydrogen concentration of the p-type gallium nitride semiconductor is equal to or lower than 10 percent of a p-type dopant concentration of the p-type gallium nitride semiconductor.

24. The method of fabricating a group III nitride semiconductor device according to claim 12, wherein the gallium nitride semiconductor comprises at least any of GaN, InGaN, AlGaN, and InAlGaN, and the p-type dopant includes magnesium.

25. A group III nitride semiconductor device comprising:
a substrate;
an active layer provided on a primary surface of the substrate and constituted by a gallium nitride semiconductor; and
a p-type gallium nitride semiconductor region provided on the primary surface of the substrate, the p-type gallium nitride semiconductor region having a gallium nitride semiconductor surface,
the gallium nitride semiconductor surface being inclined with respect to a reference plane perpendicular to a reference axis, and the reference axis extending in a direction of a c-axis of the p-type gallium nitride semiconductor region,
the p-type gallium nitride semiconductor region including a p-type dopant and hydrogen, and
a hydrogen concentration of the p-type gallium nitride semiconductor region being equal to or lower than 10 percent of a p-type dopant concentration of the p-type gallium nitride semiconductor region.

26. The group III nitride semiconductor device according to claim 25, further comprising an electrode inn contact with the gallium nitride semiconductor surface of the p-type gallium nitride semiconductor region,
the p-type dopant including magnesium, and
a junction interface between the electrode and the gallium nitride semiconductor surface of the p-type gallium nitride semiconductor region being inclined with respect to the reference plane.

27. The group III nitride semiconductor device according to claim 25, further comprising an n-type gallium nitride semiconductor region provided on the substrate,
wherein
a primary surface of the substrate includes comprises a group III nitride,
the primary surface of the substrate exhibits semipolar nature,
the n-type gallium nitride semiconductor region, the active layer, and the p-type gallium nitride semiconductor region are arranged in a direction of an axis normal to the primary surface of the substrate,
the normal axis is inclined with respect to the reference axis, and
the active layer is provided between the n-type gallium nitride semiconductor region and the p-type gallium nitride semiconductor region.

28. The group III nitride semiconductor device according to claim 25, wherein
the inclination is formed in a direction from a c-axis to an m-axis of the p-type gallium nitride semiconductor region, and
an angle of the inclination is in a range of 63 degree or more and less than 80 degrees.

29. The group III nitride semiconductor device according to claim 25, wherein the active layer is provided so as to emit light having a wavelength in a range of 480 nm or more and 540 nm or less.

30. The group III nitride semiconductor device according to claim 25, wherein the active layer is provided so as to emit light having a wavelength in a range of 510 nm or more and 540 nm or less.
